(19) United States
(12) Patent Application Publication
(10) Pub. No.: US 2026/0096289 A1
(43) Pub. Date: Apr. 2, 2026

(54) THIN FILM TRANSISTOR HAVING HYDROGEN CONTROL LAYER AND DISPLAY APPARATUS COMPRISING THE SAME

(71) Applicant: LG Display Co., Ltd., Seoul (KR)

(72) Inventors: Hochang LEE, Paju-si (KR); ChanYong JEONG, Paju-si (KR); DaeHwan KIM, Paju-si (KR)

(73) Assignee: LG Display Co., Ltd., Seoul (KR)

(21) Appl. No.: 19/313,158

(22) Filed: Aug. 28, 2025

(30) Foreign Application Priority Data
Sep. 27, 2024 (KR) 10-2024-0131398

(51) Int. Cl. H10K 59/121; H10K 59/126

(52) U.S. Cl. CPC H10K 59/1213; H10K 59/126

(57) ABSTRACT

A thin film transistor and a display apparatus including the thin film transistor are discussed. The thin film transistor can include an active layer, a gate electrode spaced apart from the active layer, and a gate insulating film between the active layer and the gate electrode. The gate insulating film includes an insulating layer, a hydrogen control layer on the insulating layer, and a hydrogen supply layer on the hydrogen control layer. The hydrogen supply layer has a higher hydrogen concentration than the insulating layer, and in a region where the gate electrode and the active layer overlap in a plan view, a portion of the active layer overlaps the hydrogen control layer and another portion of the active layer does not overlap the hydrogen control layer.

### CROSS-REFERENCE TO RELATED APPLICATION

This application claims priority to Korean Patent Application No. 10-2024-0131398, filed in the Republic of Korea on Sep. 27, 2024, which is hereby incorporated by reference in its entirety.

### BACKGROUND

### Field of Technology

The present disclosure relates to a thin film transistor (TFT) having a hydrogen control layer and a display apparatus including the same.

### Discussion of the Related Art

Since thin film transistors can be manufactured on glass or plastic substrates, they are widely used as switching elements or driving elements in display apparatuses such as liquid crystal display apparatuses or organic light emitting devices.

Thin film transistors can be classified into different types depending the material of its active layer. For example, the thin film transistor can be categorized as an amorphous silicon thin film transistor in which amorphous silicon is used as the active layer, a polycrystalline silicon thin film transistor in which polycrystalline silicon is used as the active layer, or an oxide semiconductor thin film transistor in which oxide semiconductor is used as the active layer.

Among these types of thin film transistors, the oxide semiconductor thin film transistor (oxide semiconductor TFT) that have a high mobility and a large resistance variation depending on the oxygen content have the advantage of being able to easily obtain desired property. Since the oxide constituting the active layer can be formed at a relatively low temperature during the manufacturing process of oxide semiconductor thin film transistors, the manufacturing cost is low. In addition, since the oxide semiconductors are transparent due to the nature of oxides, they are also advantageous in implementing transparent display.

However, when the oxide semiconductor thin film transistor is driven, a strong electric field is applied to the drain portion. As a strong electric field is applied to the drain portion, carriers having large kinetic energy can be trapped in the drain portion or concentrated in the drain portion. As a result, when the oxide semiconductor thin film transistor is used for a long time, heat can be generated in the drain portion, and the drain portion can be damaged. For example, in the drain portion to which a strong horizontal electric field is applied, carriers having large kinetic energy, which are hot carriers, can damage the drain portion.

If the carriers with high kinetic energy are trapped or concentrated in the drain portion, the drain portion of the oxide semiconductor can be damaged, and thus, a defect can occur in the thin film transistor.

Therefore, in order to prevent or minimize damage and defects in the oxide semiconductor thin film transistors, it is necessary to alleviate the phenomenon of a strong electric field being applied to the drain portion.

### SUMMARY OF THE DISCLOSURE

One or more embodiments of the present disclosure provide a technology for selectively supplying hydrogen to an active layer using a hydrogen control layer.

One or more embodiments of the present disclosure provide a technology for preventing or minimizing damage to an active layer by alleviating an electric field applied to a drain portion and preventing or minimizing damage or failure of an oxide semiconductor thin film transistor.

One or more embodiments of the present disclosure provide a thin film transistor in which electric field concentration is prevented or eliminated at the drain connection side of an active layer.

One or more embodiments of the present disclosure a thin film transistor including a gate insulating film having a hydrogen supply layer and a hydrogen control layer.

One or more embodiments of the present disclosure provide a technology for increasing the carrier concentration at the drain connection side of an active layer by supplying hydrogen to the drain connection side of an active layer using a hydrogen supply layer and a hydrogen control layer. One or more embodiments of the present disclosure provide a thin film transistor in which the carrier concentration on the drain connection side of an active layer is increased, thereby preventing or eliminating electric field concentration on the drain connection side.

Another embodiment of the present disclosure provides a display apparatus including the thin film transistor discussed above.

One or more embodiments of the present disclosure for achieving the above technical subject provide a thin film transistor including an active layer, a gate electrode spaced apart from the active layer, and a gate insulating film between the active layer and the gate electrode, wherein the gate insulating film includes an insulating layer, a hydrogen control layer on the insulating layer, and a hydrogen supply layer on the hydrogen control layer, wherein the hydrogen supply layer has a higher hydrogen concentration than the insulating layer, and wherein in a region where the gate electrode and the active layer overlap in a plan view, a portion of the active layer overlaps the hydrogen control layer and another portion of the active layer does not overlap the hydrogen control layer.

According to aspects of the present disclosure, the active layer can include a channel part overlapping the gate electrode, a source connection part connected to one side of the channel part, and a drain connection part connected to the other side of the channel part, wherein a portion of the channel part adjacent to the source connection part overlaps the hydrogen control layer, and a portion of the channel part adjacent to the drain connection part does not overlap the hydrogen control layer.

According to aspects of the present disclosure, the hydrogen control layer may not overlap a boundary between the channel part and the drain connection part in a plan view.

According to aspects of the present disclosure, the channel part can include an effective channel part overlapping the hydrogen control layer and an offset portion not overlapping the hydrogen control layer.

According to aspects of the present disclosure, the offset portion can have a higher carrier concentration than the effective channel part.

According to aspects of the present disclosure, the carrier concentration of the above offset portion can increase in a direction from the effective channel part toward the drain connection part.

According to aspects of the present disclosure, the hydrogen control layer includes metal oxide, and the metal oxide can include at least one of aluminum (Al), tungsten (W), titanium (Ti), chromium (Cr), vanadium (V), manganese (Mn), tantalum (Ta), hafnium (Hf), zirconium (Zr), nickel (Ni), molybdenum (Mo), and beryllium (Be).

According to aspects of the present disclosure, the hydrogen supply layer can have a higher hydrogen concentration than the insulating layer.

According to aspects of the present disclosure, the insulating layer can include at least one of silicon oxide (SiOx), aluminum oxide (AlOx), tantalum oxide (TaOx), hafnium oxide (HfOx), and zirconium oxide (ZrOx), and the hydrogen supply layer includes silicon nitride (SiNx).

According to aspects of the present disclosure, the hydrogen control layer can have a thickness of 5 nm to 10 nm.

According to aspects of the present disclosure, the gradient of the carrier concentration variation at a boundary where the channel part and the drain connection part are in contact is smaller than the gradient of the carrier concentration variation at a boundary where the channel part and the source connection part are in contact.

According to aspects of the present disclosure, the thin film transistor further includes a source electrode and a drain electrode spaced apart from each other and contact the active layer, respectively, and the active layer includes a source contact part contacting the source electrode, a drain contact part contacting the drain electrode, and a channel part between the source contact part and the drain contact part, wherein a portion of the channel part adjacent to the source contact part can overlap with the hydrogen control layer, and a portion of the channel part adjacent to the drain contact part may not overlap with the hydrogen control layer.

According to aspects of the present disclosure, the channel part can include an effective channel part overlapping the hydrogen control layer and an offset portion not overlapping the hydrogen control layer.

According to aspects of the present disclosure, the offset portion can have a higher carrier concentration than the effective channel part.

According to aspects of the present disclosure, the active layer can include a first oxide semiconductor layer and a second oxide semiconductor layer on the first oxide semiconductor layer.

Another embodiment of the present disclosure provides a display apparatus including the thin film transistor described above.

### BRIEF DESCRIPTION OF THE DRAWINGS

The above aspects and other objects, features and other advantages of the present disclosure will be more clearly understood from the following detailed description taken in conjunction with the accompanying drawings, in which:

FIG. 1 is a plan view of a thin film transistor according to one or more embodiments of the present disclosure.

FIG. 2 is a cross-sectional view taken along line I-I′ of FIG. 1.

FIG. 3 is a schematic diagram explaining hydrogen supply and hydrogen blocking by the hydrogen supply layer and the hydrogen control layer.

FIG. 4 is a graph explaining a carrier concentration distribution in an active layer.

FIG. 5 is a cross-sectional view of a thin film transistor according to another embodiment of the present disclosure.

FIGS. 6A, 6B and 6C are cross-sectional views of a thin film transistor according to another embodiment of the present disclosure, respectively.

FIG. 7 is a cross-sectional view of a thin film transistor according to another embodiment of the present disclosure.

FIG. 8 is a cross-sectional view of a thin film transistor according to another embodiment of the present disclosure.

FIG. 9 is a cross-sectional view of a thin film transistor according to another embodiment of the present disclosure.

FIG. 10 is a cross-sectional view of a thin film transistor according to another embodiment of the present disclosure.

FIG. 11 is a schematic diagram of a display apparatus according to another embodiment of the present disclosure.

FIG. 12 is a circuit diagram for one pixel of FIG. 11.

FIG. 13 is a plan view of the pixel of FIG. 12.

FIG. 14 is a cross-sectional view taken along line II-II′ of FIG. 13.

### DETAILED DESCRIPTION OF THE EMBODIMENTS

The advantages and features of the present disclosure, and the method for achieving them, will become clear with reference to the embodiments described in detail below together with the accompanying drawings. However, the present disclosure is not limited to the embodiments disclosed below, but can be implemented in various different forms. These embodiments are intended to make the disclosure of the present disclosure complete and to enable those skilled in the art to easily understand the invention.

The shapes, sizes, ratios, angles, numbers, or the like. disclosed in the drawings for explaining embodiments of the present disclosure are examples, and the present disclosure is not limited to the matters illustrated in the drawings. The same components can be referred to by the same reference numerals throughout the specification. In addition, in explaining the present disclosure, if it is determined that a detailed description of a related known technology can unnecessarily obscure the gist of the present disclosure, the detailed description is omitted.

In this specification, when the words “includes,” “has,” “consists of,” or the like. are used, other parts can be added unless the expression “only” is used. When a component is expressed in the singular, the plural is included unless otherwise explicitly stated.

When interpreting a component, it is interpreted as including the error range even though there is no separate explicit description.

For example, when the positional relationship between two parts is described as “on˜”, “above˜”, “below˜”, “next to˜”, or the like, one or more other parts can be located between the two parts, unless the expression “right” or “directly” is used.

The spatially relative terms “below,” “beneath,” “lower,” “above,” “upper,” and the like can be used to easily describe the relationship of one element or component to another element or component, as illustrated in the drawings. The spatially relative terms should be understood to include different orientations of the elements during use or operation in addition to the orientations depicted in the drawings. For example, if an element illustrated in the drawings is flipped over, an element described as “below” or “beneath” another element can end up being placed “above” the other element. Thus, the term “below” can include both the above and below directions. Likewise, the term “above” or “above” can include both the above and below directions.

When describing a temporal relationship, for example, when describing a temporal relationship such as “after”, “following”, “next to”, “before”, or the like, it can also include cases where there is no continuity, as long as the expression “right away” or “directly” is not used.

Although the terms first, second, or the like. are used to describe various components, these components are not limited by these terms. These terms are only used to distinguish one component from another. Accordingly, a first component referred to below can also be a second component within the technical concept of the present disclosure.

At least one term should be understood to include all combinations that can be presented from one or more of the associated items. For example, the meaning of “at least one of the first, second, and third items” can mean not only each of the first, second, or third items, but also all combinations of items that can be presented from two or more of the first, second, and third items. Further, the term “can” fully encompasses all the meanings and coverages of the term “may” and vice versa.

The individual features of the various embodiments of the present disclosure can be partially or wholly combined or combined with each other, and can be technically interconnected and driven in various ways, and each embodiment can be implemented independently of each other or can be implemented together in a related relationship.

When adding reference numerals to components of each drawing describing embodiments of the present disclosure, identical components can have the same numerals as much as possible even though they are shown in different drawings.

In the embodiments of the present disclosure, the source electrode and the drain electrode are distinguished only for convenience of explanation, and the source electrode and the drain electrode can be interchanged. In addition, the source electrode of one embodiment can become the drain electrode in another embodiment, and the drain electrode of one embodiment can become the source electrode in another embodiment.

In some embodiments of the present disclosure, for convenience of explanation, the source connection part and the source electrode are distinguished, and the drain connection part and the drain electrode are distinguished, but the embodiments of the present disclosure are not limited thereto. The source connection part can be the source electrode, and the drain connection part can be the drain electrode. In addition, the source connection part can be the drain electrode, and the drain connection part can be the source electrode.

Various embodiment of the present disclosure will now be described by referring to the drawings. All the components of each display device/apparatus according to all embodiments of the present disclosure are operatively coupled and configured.

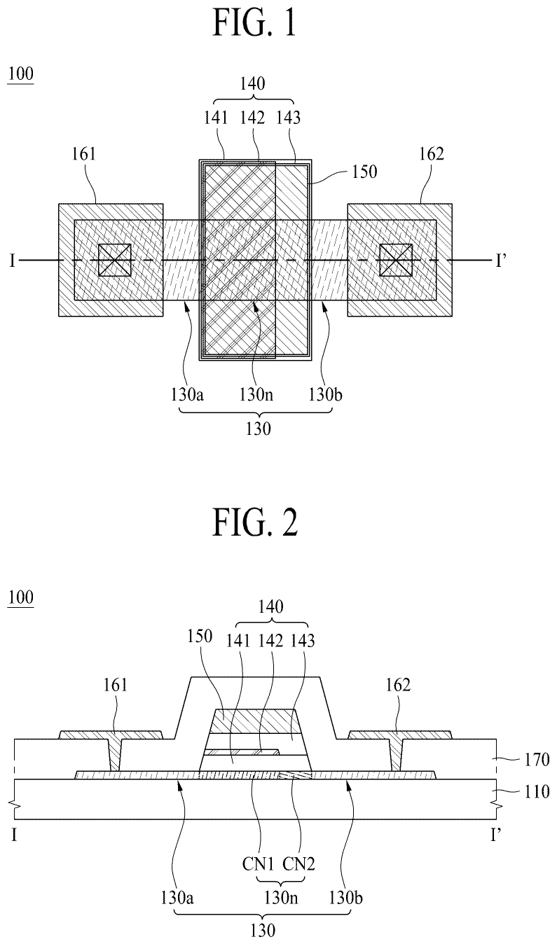

FIG. 1 is a plan view of a thin film transistor 100 according to one or more embodiments of the present disclosure, and FIG. 2 is a cross-sectional view taken along line II′ of FIG. 1.

Referring to FIG. 1 and FIG. 2, a thin film transistor 100 according to one or more embodiments of the present disclosure includes an active layer 130, a gate electrode 150, and a gate insulating film 140. The gate electrode 150 is spaced apart from the active layer 130. The gate insulating film 140 is disposed between the active layer 130 and the gate electrode 150. The gate insulating film 140 includes an insulating layer 141, a hydrogen control layer 142, and a hydrogen supply layer 143.

According to one embodiment of the present disclosure, in a region where the gate electrode 150 and the active layer 130 overlap in a plan view, a part of the active layer 130 overlaps with the hydrogen control layer 142, and another part of the active layer 130 does not overlap with the hydrogen control layer 142.

Referring to FIG. 2, the thin film transistor 100 can be disposed on a substrate 110.

The substrate 110 supports components of the thin film transistor 100. Anything that supports the thin film transistor 100 can be referred to as the substrate 110 without limitation.

A glass substrate or a polymer resin substrate can be used as the substrate 110. As the polymer resin substrate, there is a plastic substrate. The plastic substrate can include at least one of polyimide (PI), polycarbonate (PC), polyethylene (PE), polyester, polyethylene terephthalate (PET), and polystyrene (PS), which have flexible property. When a plastic is used as the substrate 110, considering that a high-temperature deposition process is performed on the substrate 110, a heat-resistant plastic that can withstand high temperatures can be used.

The active layer 130 is disposed on the substrate 110. According to one embodiment of the present disclosure, a buffer layer can be disposed on the substrate 110, and the active layer 130 can be disposed on the buffer layer.

According to one embodiment of the present disclosure, the active layer 130 includes an oxide semiconductor material. According to one embodiment of the present disclosure, the active layer 130 is, for example, an oxide semiconductor layer made of an oxide semiconductor material.

The active layer 130 can include at least one oxide semiconductor material, for example, selected from IGZO (InGaZnO) based, IGO (InGaO) based, IGZTO (InGaZnSnO) based, GZTO (GaZnSnO) based, GZO (GaZnO) based, GO (GaO) based, TO (SnO) based, ITO (InSnO) based, ITZO (InSnZnO) based, IZO (InZnO) based, ZO (ZnO) based, IO (InO) based, and FIZO (FeInZnO) based oxide semiconductor material.

The active layer 130 can have a single layer structure or can have a multilayer structure including two or more oxide semiconductor layers.

According to one embodiment of the present disclosure, the active layer 130 can include a channel part 130n, a source connection part 130a, and a drain connection part 130b.

The channel part 130n overlaps with the gate electrode 150. The channel part 130n has semiconductor characteristic. Depending on the voltage applied to the gate electrode 150, the channel part 130n can have an electric characteristic like a conductor or an electric characteristic like an insulator.

The source connection part 130a is connected to one side of the channel part 130n, and the drain connection part 130b is connected to the other side of the channel part 130n. The source connection part 130a and the drain connection part 130b are spaced apart from each other, with the channel part 130n interposed therebetween.

According to one embodiment of the present disclosure, the source connection part 130a and the drain connection part 130b do not overlap with the gate electrode 150. The source connection part 130a and the drain connection part 130b can also be referred to as a conductorized portion.

The source connection 130a and a drain connection 130b can be formed by selective conductorization of the active layer 130. For example, the oxide semiconductor material constituting the active layer 130 can be selectively conductorized to form the source connection 130a and the drain connection 130b. According to one embodiment of the present disclosure, selective conductorization can also be referred to as metallization.

According to one embodiment of the present disclosure, selective conductorization refers to improving the electrical conductivity of a selected portion of the active layer 130 or imparting electrical conductivity to the selected portion. A portion of the active layer 130 that is selectively conductorized has excellent electrical conductivity and can function as a wiring portion.

For example, selective conductorization can be achieved by doping a selected region of the active layer 130 with a dopant. In this case, the source connection part 130a and the drain connection part 130b can include a dopant.

In detail, doping can be accomplished by ion implantation. Dopant ions can be doped into a selected region of the active layer 130 by ion implantation. The dopant can include, for example, at least one of boron (B), phosphorus (P), fluorine (F), and hydrogen (H).

In addition, according to one embodiment of the present disclosure, a selected portion of the active layer 130 can be conductorized by plasma treatment, so that a source connection part 130a and a drain connection part 130b can be formed. For example, in the patterning process of the gate insulating film 140 or the gate electrode 150, selective conductorization can be performed by plasma treatment, so that a source connection part 130a and a drain connection part 130b can be formed.

According to one embodiment of the present disclosure, a portion of the active layer 130 exposed from the gate insulating film 140 can be subjected to plasma treatment, thereby forming a source connection part 130a and a drain connection part 130b.

According to one embodiment of the present disclosure, the source connection part 130a and the drain connection part 130b can each have electric characteristic similar to metal.

A gate insulating film 140 is disposed on the active layer 130.

Referring to FIG. 2, the gate insulating film 140 can have a patterned structure.

For example, the gate insulating film 140 can be patterned into the same shape as the gate electrode 150. During the patterning process of the gate insulating film 140 and the gate electrode 150, selective conductorization can be achieved, so that the source connection part 130a and the drain connection part 130b can be formed. For example, during the patterning process of the gate insulating film 140 and the gate electrode 150, selective conductorization can be achieved in a plasma treatment process, so that the source connection part 130a and the drain connection part 130b can be formed.

The gate insulating film 140 includes an insulating layer 141, a hydrogen control layer 142, and a hydrogen supply layer 143. According to one embodiment of the present disclosure, in the gate insulating film 140, the hydrogen control layer 142 can be placed between the insulating layer 141 and the hydrogen supply layer 143.

Referring to the laminated structure of the gate insulating film 140 illustrated in FIG. 2, an insulating layer 141 is disposed on the active layer 130. The insulating layer 141 has excellent insulating property and protects the channel part 130n of the active layer 130. In addition, the insulating layer 141 has a low hydrogen concentration. For example, the insulating layer 141 can have a lower hydrogen concentration than the hydrogen supply layer 143.

As the insulating layer 141, for example, at least one of silicon oxide (SiOx), aluminum oxide (AlOx), tantalum oxide (TaOx), hafnium oxide (HfOx), and zirconium oxide (ZrOx) can be used. Among these, silicon oxide (SiOx) has excellent insulating property and can be made to have a low hydrogen concentration, and thus can be usefully used as the insulating layer 141. However, an embodiment of the present disclosure is not limited to the examples described above, and other known insulating materials can be applied to the insulating layer 141. In detail, in order to have excellent insulating property, an oxide of a metal having a relatively large energy bandgap can be used as a material of the insulating layer 141.

A hydrogen control layer 142 is disposed on the insulating layer 141.

The hydrogen control layer 142 can block hydrogen (H). The hydrogen control layer 142 can be made of a hydrogen blocking material or a hydrogen absorbing material. For example, the hydrogen control layer 142 can include a metal oxide. The metal oxide included in the hydrogen control layer 142 can include at least one of aluminum (Al), tungsten (W), titanium (Ti), chromium (Cr), vanadium (V), manganese (Mn), tantalum (Ta), hafnium (Hf), zirconium (Zr), nickel (Ni), molybdenum (Mo), and beryllium (Be).

The hydrogen control layer 142 can cover a part of the active layer 130. Referring to FIG. 1 and FIG. 2, in a region where the gate electrode 150 and the active layer 130 overlap in a plan view, a part of the active layer 130 overlaps with the hydrogen control layer 142, and another part of the active layer 130 does not overlap with the hydrogen control layer 142. The detailed configuration of the hydrogen control layer 142 will be described later.

A hydrogen supply layer 143 is disposed on the hydrogen control layer 142.

The hydrogen supply layer 143 has a higher hydrogen concentration than the insulating layer 141. The hydrogen supply layer 143 selectively supplies hydrogen to the active layer 130. In detail, the hydrogen supply layer 143 supplies hydrogen to a region of the active layer 130 that does not overlap with the hydrogen control layer 142.

The hydrogen supply layer 143 can be made of a material containing a large amount of hydrogen. In detail, the hydrogen supply layer 143 can be made of an insulating material containing a large amount of hydrogen.

According to one embodiment of the present disclosure, the hydrogen supply layer 143 can include silicon nitride (SiNx). However, one embodiment of the present disclosure is not limited thereto, and other insulating materials rich in hydrogen content can be applied to the hydrogen supply layer 143.

According to one embodiment of the present disclosure, the hydrogen supply layer 143 is disposed between the hydrogen control layer 142 and the gate electrode 150. Additionally, the insulating layer 141 is disposed between the active layer 130 and the hydrogen control layer 142.

A gate electrode 150 is disposed on a gate insulating film 140. The gate electrode 150 is spaced apart from the active layer 130 and overlaps at least a part of the active layer 130. The gate electrode 150 overlaps with the channel part 130n of the active layer 130.

In addition, a portion of the gate electrode 150 overlaps the hydrogen control layer 142.

The gate electrode 150 can include at least one of an aluminum based metal such as aluminum (Al) or an aluminum alloy, a silver based metal such as silver (Ag) or a silver alloy, a copper based metal such as copper (Cu) or a copper alloy, a molybdenum based metal such as molybdenum (Mo) or a molybdenum alloy, chromium (Cr), tantalum (Ta), neodymium (Nd), and titanium (Ti). The gate electrode 150 can also have a multilayer film structure including at least two conductive films having different physical property.

An interlayer insulating layer 170 can be disposed on the gate electrode 150. The interlayer insulating layer 170 is an insulating layer made of an insulating material. In detail, the interlayer insulating layer 170 can be made of an organic material, an inorganic material, or a laminate of an organic material layer and an inorganic material layer.

The source electrode 161 and a drain electrode 162 are disposed on the interlayer insulating layer 170. The source electrode 161 and the drain electrode 162 are spaced apart from each other and are each connected to an active layer 130. The source electrode 161 and the drain electrode 162 can each be connected to the active layer 130 through a contact hole penetrating the interlayer insulating layer 170.

The source electrode 161 and the drain electrode 162 each can include at least one of molybdenum (Mo), aluminum (Al), chromium (Cr), gold (Au), titanium (Ti), nickel (Ni), neodymium (Nd), copper (Cu), and alloys thereof. The source electrode 161 and the drain electrode 162 each can be formed of a single layer made of a metal or an alloy of metals, or can be formed of a multilayer structure having two or more layers.

Hereinafter, the hydrogen control layer 142 is described in more detail.

According to one embodiment of the present disclosure, the hydrogen control layer 142 can block hydrogen (H) by blocking the flow of hydrogen (H) or by absorbing hydrogen (H).

According to one embodiment of the present disclosure, the hydrogen control layer 142 can have excellent chemical stability. The hydrogen control layer 142 can block or capture hydrogen (H).

According to one embodiment of the present disclosure, the hydrogen control layer 142 can include a metal oxide. Accordingly, the hydrogen control layer 142 includes a metal atom and an oxygen atom. According to one embodiment of the present disclosure, the hydrogen control layer 142 can be in a stoichiometrically stable oxide state.

The hydrogen control layer 142 can include at least one of aluminum (Al), tungsten (W), titanium (Ti), chromium (Cr), vanadium (V), manganese (Mn), tantalum (Ta), hafnium (Hf), zirconium (Zr), nickel (Ni), molybdenum (Mo), and beryllium (Be) as a metal. According to one embodiment of the present disclosure, the hydrogen control layer 142 can include at least one of an aluminum (Al) based oxide, a tungsten (W) based oxide, a titanium (Ti) based oxide, a chromium (Cr) based oxide, a vanadium (V) based oxide, a manganese (Mn) based oxide, a tantalum (Ta) based oxide, a hafnium (Hf) based oxide, a zirconium (Zr) based oxide, a nickel (Ni) based oxide, a molybdenum (Mo) based oxide, and a beryllium (Be) based oxide.

The hydrogen control layer 142 can have insulating property and can maintain a stable bond with the insulating layer 141 and the hydrogen supply layer 143. The hydrogen control layer 142 can have a thickness smaller than a thickness of the insulating layer 141 or a thickness of the hydrogen supply layer 143.

According to one embodiment of the present disclosure, the hydrogen control layer 142 can have a thickness of 5 nm to 10 nm. If the thickness of the hydrogen control layer 142 is less than 5 nm, the hydrogen control layer 142 may not sufficiently block hydrogen. In addition, if the thickness of the hydrogen control layer 142 is designed to be less than 5 nm, the hydrogen control layer 142 can be damaged easily and can have a deteriorated mechanical stability.

In detail, when the thickness of the hydrogen control layer 142 is less than 5 nm, the hydrogen control layer 142 may not sufficiently protect the active layer 130 due to the thin thickness. In addition, when the thickness of the hydrogen control layer 142 is designed to be less than 5 nm, the hydrogen control layer 142 can be easily damaged due to the thin thickness, and mechanically unstable. Therefore, according to one embodiment of the present disclosure, the thickness of the hydrogen control layer 142 can be designed to be 5 nm or more.

On the other hand, if the thickness of the hydrogen control layer 142 exceeds 10 nm, the thickness of the gate insulating film 140 can become thicker unnecessarily. Therefore, according to one embodiment of the present disclosure, the thickness of the hydrogen control layer 142 can be designed to be 10 nm or less.

In detail, according to one embodiment of the present disclosure, the hydrogen control layer 142 can have a thickness of 5 to 7 nm.

According to one embodiment of the present disclosure, the hydrogen control layer 142 is designed to cover a part of the channel part 130n in a plan view and not cover another part of the channel part 130n.

Referring to FIG. 1, the hydrogen control layer 142 is disposed on a portion of the active layer 130. In detail, the hydrogen control layer 142 is disposed on a portion of the channel part 130n.

Referring to FIG. 1 and FIG. 2, the hydrogen control layer 142 is disposed on a portion of the channel part 130n located at the side of the source connection part 130a, which can be referred to as an effective channel part CN1. The hydrogen control layer 142 can be disposed to overlap with at least half of the area of the channel part 130n.

The hydrogen control layer 142 overlaps a portion of the channel part 130n located at the side of the source connection part 130a, and does not overlap a portion of the channel part 130n located at the side of the drain connection part 130b, which can be referred to as an offset portion CN2.

According to one embodiment of the present disclosure, a portion of the channel part 130n toward the source connection part 130a overlaps with the hydrogen control layer 142, and a portion of the channel part 130n toward the drain connection part 130b does not overlap with the hydrogen control layer 142.

Based on the plan view, the hydrogen control layer 142 can have a shape disposed to extend from the boundary between the channel part 130n and the source connection part 130a toward the drain connection part 130b. For example, the hydrogen control layer 142 can be disposed on the upper portion of the region extending from the boundary between the channel part 130n and the source connection part 130a toward the drain connection part 130b.

In addition, the hydrogen control layer 142 does not overlap the boundary between the channel part 130n and the drain connection part 130b.

Referring to FIG. 2, the channel part 130n can include an effective channel part CN1 overlapping with the hydrogen control layer 142 and an offset portion CN2 not overlapping with the hydrogen control layer 142. One side of the effective channel part CN1 can contact the source connection part 130a, and the other side of the effective channel part CN1 can contact the offset portion CN2. One side of the offset portion CN2 can contact the effective channel part CN1, and the other side of the offset portion CN2 can contact the drain connection part 130b.

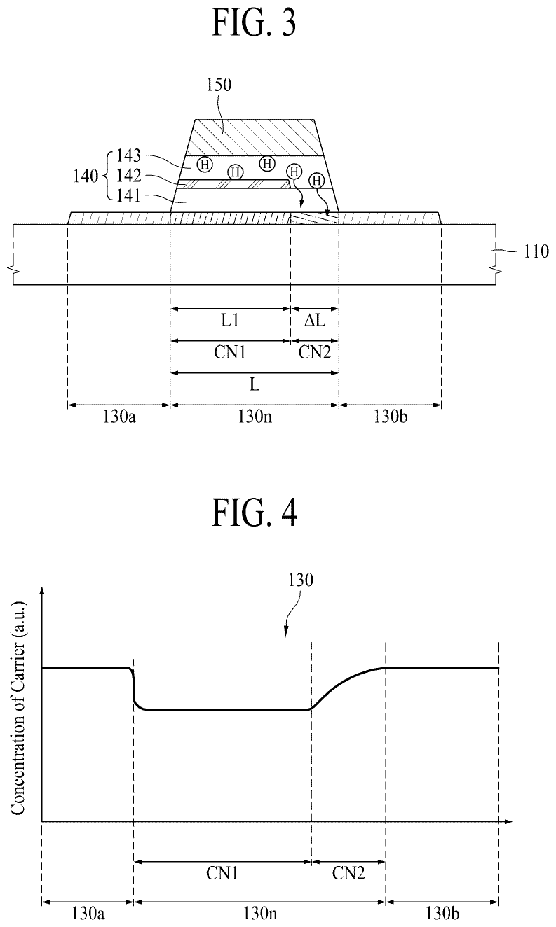

FIG. 3 is a schematic diagram explaining the supply and blocking of hydrogen by the hydrogen supply layer 143 and the hydrogen control layer 142 according to one or more embodiments of the present disclosure.

Referring to FIG. 3, the hydrogen in the hydrogen supply layer 143 can move to the channel part 130n through an area of the gate insulating film 140 where the hydrogen control layer 142 is not disposed.

Since the offset portion CN2 does not overlap with the hydrogen control layer 142, it is not protected by the hydrogen control layer 142. Therefore, hydrogen in the hydrogen supply layer 143 can diffuse into the offset portion CN2. Therefore, the offset portion CN2 can have a higher hydrogen concentration than the effective channel part CN1.

Hydrogen (H) supplied to the offset portion CN2 can bond with the elements of the active layer 130, and can exist in various bonding forms in the active layer 130. For example, hydrogen (H) supplied to the offset portion CN2 can bond with a metal M (MH) or can bond with an element at an oxygen vacancy Vo site (e.g., “Vo”+“O—H”, or the like). As a result, a shallow donor state can increase, thereby forming free electrons, and thus, a carrier concentration in the offset portion CN2 can increase.

According to one embodiment of the present disclosure, the offset portion CN2 can have a higher carrier concentration than the effective channel part CN1.

Meanwhile, the portion of the channel part 130n contacting the drain connection part 130b is not protected by the hydrogen control layer 142, and is not sufficiently protected by the gate electrode 150. Therefore, the portion of the channel part 130n contacting the drain connection part 130b is affected by external factors and can be affected by the conductorization process. Due to this effect, the portion of the channel part 130n contacting the drain connection part 130b can have a relatively high carrier concentration.

Therefore, according to one embodiment of the present disclosure, the carrier concentration of the offset portion CN2 can increase along the direction from the effective channel part CN1 toward the drain connection part 130b.

FIG. 4 is a graph explaining the carrier concentration distribution of the active layer 130 according to one or more embodiments of the present disclosure.

Since the offset portion CN2 does not overlap with the hydrogen control layer 142, hydrogen from the hydrogen supply layer 143 can be supplied to the offset portion CN2. The hydrogen (H) supplied to the offset portion CN2 can form a bond with a metal M or with an element at oxygen vacancy Vo position, thereby increasing a shallow donor state. As a result, free electrons can be formed, and the carrier concentration of the offset portion CN2 can increase.

In addition, the part of the offset portion CN2 contacting the drain connection part 130b is not protected by the hydrogen control layer 142, and not sufficiently protected by the gate electrode 150. Therefore, the part of the offset portion CN2 contacting the drain connection part 130b can be indirectly affected by the conductorization process. Due to this effect, the part of the offset portion CN2 that contacting the drain connection part 130b can have a relatively high carrier concentration. Accordingly, the offset portion CN2 can have a gradient of carrier concentration that gradually increases from the boundary between the effective channel part CN1 and the offset portion CN2 toward the drain connection part 130b. As a result, a carrier concentration distribution as illustrated in FIG. 4 can occur.

Referring to FIG. 4, the offset portion CN2 can have a gradient of carrier concentration that gradually increases along the direction from the effective channel part CN1 toward the drain connection part 130b.

During the operation of a device to which the thin film transistor 100 is applied, for example, during operation of a display apparatus, sometimes a high voltage is applied to the drain connection part 130b of the thin film transistor 100. In this case, a strong electric field, for example, a strong horizontal electric field can be applied at the side the drain connection part 130b, in detail, a relatively high horizontal electric field can be applied to a portion of the channel part 130n near the drain connection part 130b. As a result, carriers can be accelerated at the side of the drain connection part 130b, and hot carriers having high energy can be formed. These hot carriers can damage the channel part 130n and the drain connection part 130b.

According to one embodiment of the present disclosure, as illustrated in FIG. 4, the concentration of carriers gradually increases in the offset portion CN2, which is a portion of the channel part 130n corresponding to a side of the drain connection part 130b. As a result, the electric field concentration in the channel part 130n near the drain connection part 130b, i.e., in the offset portion CN2 can be alleviated.

According to one embodiment of the present disclosure, since the horizontal electric field gradually changes in a portion of the channel part 130n adjacent to the drain connection part 130b, which is offset portion CN2, acceleration of carriers can be prevented. As a result, formation of hot carriers can be suppressed, and damage to the channel part 130n by hot carriers can be prevented.

According to one embodiment of the present disclosure, as can be seen in FIG. 4, the slope of the graph of the carrier concentration at the portion where the channel part 130n and the drain connection part 130b are in contact is smaller than the slope of the graph of the carrier concentration at the portion where the channel part 130n and the source connection part 130a are in contact. That is, the gradient of the carrier concentration at a boundary portion between the channel part 130n and the drain connection part 130b may be smaller than the gradient of the carrier concentration at a boundary portion between the channel part 130n and the source connection part 130a. As illustrated in FIG. 4, the carrier concentration varies rapidly at the portion where the channel part 130n and the source connection part 130a are in contact. On the other hand, the carrier concentration variation is relatively gradual at the portion where the channel part 130n and the drain connection part 130b are in contact.

In an oxide semiconductor, carriers can flow from the source connection part 130a to the drain connection part 130b, and a relatively high horizontal electric field is applied at the side of the drain connection part 130b, whereas a relatively low horizontal electric field is applied at the side of the source connection part 130a. Therefore, according to one embodiment of the present disclosure, even though an offset portion is not formed at a portion of the channel part 130n adjacent to the source connection part 130a, damage to the channel part 130n may not occur significantly.

In addition, if an offset portion is formed at the portion of the channel part 130n adjacent to the source connection part 130a, the effective channel length can be reduced. Accordingly, according to one embodiment of the present disclosure, an offset portion is not formed at the portion of the channel part 130n adjacent to the source connection part 130a.

Since an offset portion does not need to be formed at the portion of the channel part 130n adjacent to the source connection part 130a, according to one embodiment of the present disclosure, the hydrogen control layer 142 is disposed so as to cover only an entire portion of the channel part 130n at the side of the source connection part 130a, i.e., the effective channel part CN1.

According to one embodiment of the present disclosure, a direction from the source connection part 130a toward the drain connection part 130b can be referred to as a longitudinal direction of the channel part 130n. In addition, a length L of the channel part 130n can be measured along the direction from the source connection part 130a toward the drain connection part 130b. In detail, the length L of the channel part 130n can be defined as the distance between the source connection part 130a and the drain connection part 130b.

According to one embodiment of the present disclosure, the hydrogen control layer 142 can be disposed along the length direction of the channel part 130n from the boundary between the channel part 130n and the source connection part 130a.

Referring to FIG. 3, the hydrogen control layer 142 can have a length of L1 along the longitudinal direction of the channel part 130n. According to one embodiment of the present disclosure, the length of the hydrogen control layer 142 overlapping the gate electrode 150 can be referred to as L1.

The hydrogen control layer 142 can be disposed in an area that is at least half of the area overlapping the channel part 130n. The length L1 of the hydrogen control layer 142 can be at least half of the length L of the channel part 130n. In detail, the overlapping length L1 of the hydrogen control layer 142 and the channel part 130n can be designed to be at least half of the length L of the channel part 130n. In detail, the overlapping length L1 of the hydrogen control layer 142 and the channel part 130n can be in a range of 70% to 90% of the length L of the channel part 130n. The overlapping length L1 of the hydrogen control layer 142 and the channel part 130n is measured along a direction parallel to a line connecting the source connection part 130a and the drain connection part 130b.

According to one embodiment of the present disclosure, an area of the active layer 130 which overlaps with the gate electrode 150 and the hydrogen control layer 142 can become an effective channel part CN1. In addition, a length of an area overlapping with the gate electrode 150, the active layer 130, and the hydrogen control layer 142 can become the length of the effective channel part CN1.

As shown in FIG. 2 and FIG. 3, when the gate insulating film 140 is patterned to have the same shape as the gate electrode 150, the length of the hydrogen control layer 142 can be referred to as the length L1 of the effective channel part CN1.

According to one embodiment of the present disclosure, the offset portion CN2 can be a region of the channel part 130n that does not overlap with the hydrogen control layer 142. In detail, among the region where the active layer 130 and the gate electrode 150 overlap, a portion that does not overlap with the hydrogen control layer 142 can be the offset portion CN2.

The length ΔL of the offset portion CN2 can be defined as the length of the region where the active layer 130 and the gate electrode 150 overlap, but do not overlap with the hydrogen control layer 142.

Referring to FIG. 2 and FIG. 3, the length ΔL of the offset portion CN2 can be a value obtained by subtracting the length L1 of the effective channel part CN1 from the length L of the channel part 130n (ΔL=L−L1). Referring to FIG. 3, the length ΔL of the offset portion CN2 can be the length of the region where the hydrogen control layer 142 is not disposed in the region overlapping the gate electrode 150.

As illustrated in FIG. 3, hydrogen (H) of the hydrogen supply layer 143 can pass through the region where the hydrogen control layer 142 is not disposed and move to the channel part 130n. At this time, if the region where the hydrogen control layer 142 is not disposed is excessively large, the carrier concentration of the channel part 130n can increase more than necessary, so that the channel part 130n can be conductorized and thus may not be able to perform its function as a channel. On the other hand, if the region where the hydrogen control layer 142 is not disposed is too small, the amount of hydrogen supplied to the portion of the channel part 130n adjacent to the drain connection part 130b can be small, so that the electric field relaxation effect at the side of the drain region can be reduced.

Considering the above described points, the length ΔL of the region of the gate insulating film 140 on which the hydrogen control layer 142 is not disposed can be 10% to 30% of the length L of the channel part 130n. Alternatively, the length ΔL of the offset portion CN2 can be 10% to 30% of the length L of the channel part 130n. For example, the ratio of the length L1 of the effective channel part CN1 to the length ΔL of the offset portion CN2 can be in the range of 7:3 to 9:1 (L:ΔL=7:3 to 9:1). When the length ΔL of the offset portion CN2 is less than 10% of the length L of the channel part 130n, the amount of hydrogen supplied to the portion of the channel part 130n adjacent to the drain connection part 130b can be small, and thus the electric field relaxation effect at the side of the drain region can be reduced. On the other hand, if the length ΔL of the offset portion CN2 exceeds 30% of the length L of the channel part 130n, a deterioration such as the threshold voltage Vth of the thin film transistor 100 shifts excessively in the negative (-) direction can occur.

According to one embodiment of the present disclosure, the length ΔL of the offset portion CN2 can be designed to be 0.5 μm to 2.0 μm.

In detail, in the region where the active layer 130 and the gate electrode 150 overlap, a region that does not overlap with the hydrogen control layer 142 can be designed to be in the range of 0.5 μm to 2.0 μm.

When the length of the region, which overlaps the active layer 130 and the gate electrode 150 but does not overlap with the hydrogen control layer 142, is less than 0.5 μm, the amount of hydrogen supplied to the portion of the channel part 130n adjacent to the drain connection part 130b can be small, and thus the electric field relaxation effect at the side of the drain region can be reduced.

On the other hand, if the length of the region, which overlaps the active layer 130 and the gate electrode 150 but does not overlap with the hydrogen control layer 142, exceeds 2.0 μm, a deterioration such as the threshold voltage Vth of the thin film transistor 100 can excessively shift to the negative (−) direction can occur, thereby lowering the stability of the thin film transistor 100.

Meanwhile, since the length ΔL of the region of the gate insulating film 140, on which the hydrogen control layer 142 is not disposed, is designed to be 10% to 30% of the length L of the channel part 130n, the length L1 of the hydrogen control layer 142 overlapping the gate electrode 150 can be 70% to 90% of the length L of the channel part 130n.

According to one embodiment of the present disclosure, the ratio of the length L1 of the effective channel part CN1 to the length ΔL of the offset portion CN2 can be in the range of 7:3 to 9:1 (L1:ΔL=7:3 to 9:1).

In addition, according to one embodiment of the present disclosure, the ratio of the length L1 at which the gate electrode 150 and the hydrogen control layer 142 overlap and the length ΔL at which the gate electrode 150 and the hydrogen control layer 142 do not overlap can be in the range of 7:3 to 9:1 (L1:ΔL=7:3 to 9:1).

In one embodiment of the present disclosure, the source connection part 130a and the drain connection part 130b illustrated in the drawing are only distinguished for convenience of explanation, and the source connection part 130a and the drain connection part 130b can be exchanged with each other. The source connection part 130a illustrated in the drawing can become the drain connection part, and the drain connection part 130b can become the source connection part.

According to one embodiment of the present disclosure, the source connection part 130a can serve as either a source electrode or a drain electrode. Additionally, the drain connection part 130b can serve as either a drain electrode or a source electrode.

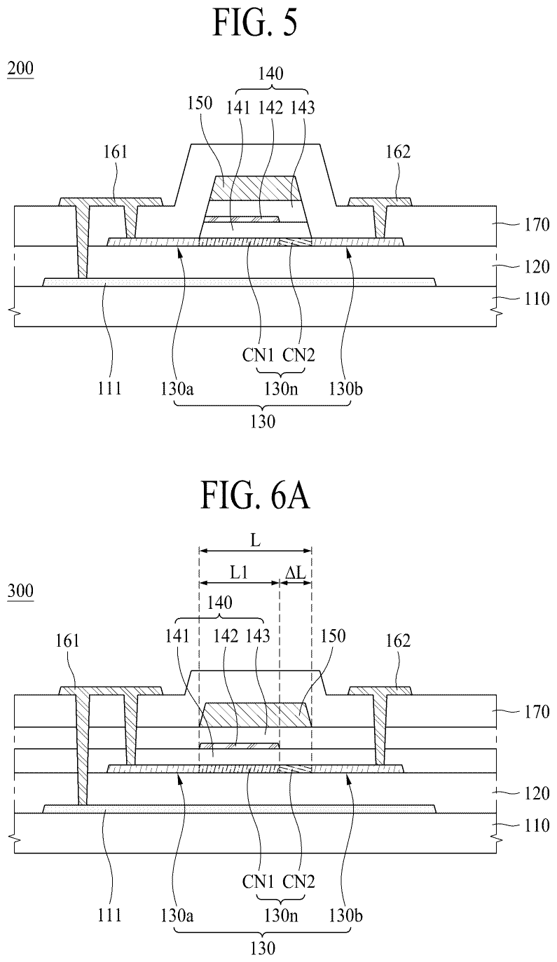

FIG. 5 is a cross-sectional view of a thin film transistor 200 according to another embodiment of the present disclosure.

Hereinafter, to avoid redundancy, descriptions of components already described are omitted, or components already described are briefly described.

Referring to FIG. 5, a light shielding layer 111 can be disposed on a substrate 110. The light shielding layer 111 has light blocking property. The light shielding layer 111 can block light incident from the substrate 110 and protect the channel part 130n of the active layer 130.

The light shielding layer 111 can be made of a material having light blocking property. The light shielding layer 111 can include at least one of an aluminum based metal such as aluminum (Al) or an aluminum alloy, a molybdenum based metal such as molybdenum (Mo) or a molybdenum alloy, chromium (Cr), tantalum (Ta), neodymium (Nd), titanium (Ti), and iron (Fe).

According to one embodiment of the present disclosure, the light shielding layer 111 can have electrical conductivity. The light shielding layer 111 can be electrically connected to any one of the source electrode 161 and the drain electrode 162. The light shielding layer 111 can be connected to the source electrode 161.

A buffer layer 120 is disposed on the light shielding layer 111. The buffer layer 120 covers the upper surface of the substrate 110 and the upper surface of the light shielding layer 111. The buffer layer 120 has insulating property and protects the active layer 130.

An active layer 130 can be disposed on a buffer layer 120.

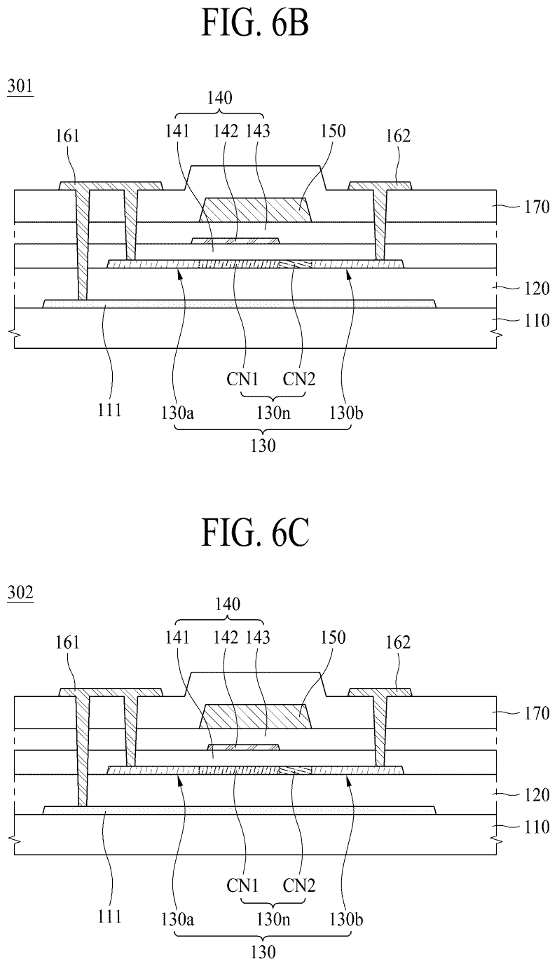

FIG. 6A is a cross-sectional view of a thin film transistor 300 according to another embodiment of the present disclosure.

Referring to FIG. 6A, the gate insulating film 140 covers the entire upper portion of the active layer 130. Additionally, the gate insulating film 140 can be disposed to cover the entire surface of the upper portion of the substrate 110.

According to another embodiment of the present disclosure, selective conductorization can be achieved by doping a selected region of the active layer 130 with a dopant. For example, doping can be achieved by ion implantation. In detail, dopant ions can be doped into a selected region of the active layer 130 by ion implantation.

According to one embodiment of the present disclosure, the dopant can include at least one of boron (B), phosphorus (P), fluorine (F), and hydrogen (H).

A portion of the active layer 130 can be selectively conductorized by dopant doping using the gate electrode 150 as a mask. As a result, a source connection part 130a and a drain connection part 130b can be formed. In this case, the source connection part 130a and the drain connection part 130b can include a dopant.

Since the offset portion CN2 does not overlap with the hydrogen control layer 142, hydrogen from the hydrogen supply layer 143 can be supplied to the offset portion CN2. Free electrons can be formed by the hydrogen (H) supplied to the offset portion CN2, and as a result, the carrier concentration of the offset portion CN2 can increase.

The drain connection part 130b contacting the offset portion CN2 is not covered by the gate electrode 150. Therefore, the portion of the offset portion CN2 contacting the drain connection part 130b can be affected by the conductorization process or the dopant. As a result, the portion of the offset portion CN2 contacting the drain connection part 130b can have a relatively high carrier concentration. As a result, the offset portion CN2 can have a gradient of carrier concentration that gradually increases toward the drain connection part 130b, as illustrated in FIG. 4.

To form a gradient of carrier concentration, the ratio of the length L1 of the effective channel part CN1 to the length ΔL of the offset portion CN2 can be in the range of 7:3 to 9:1 (L:ΔL=7:3 to 9:1).

A structure in which a light shielding layer 111 is disposed on a substrate 110 is provided. However, another embodiment of the present disclosure is not limited thereto, and the light shielding layer 111 can be omitted. If the light shielding layer 111 is omitted, the buffer layer 120 can also be omitted. The light shielding layer 111 can also be omitted in the following embodiments.

FIG. 6B is a cross-sectional view of a thin film transistor 301 according to another embodiment of the present disclosure.

According to another embodiment of the present disclosure, one end of the hydrogen control layer 142 disposed to overlap the source connection part 130a may not be aligned to correspond to one end of the gate electrode 150.

Referring to FIG. 6B, one end of the hydrogen control layer 142 disposed to overlap the source connection part 130a and protrudes from the gate electrode 150. When the protruding length of the hydrogen control layer 142 is 0.2 μm or less, the thin film transistor 301 can be driven without any problem. Here, the protruding length is a length of the hydrogen control layer 142 that protrudes from the gate electrode 150.

In detail, even though one end of the hydrogen control layer 142 disposed on the source connection part 130a protrudes from the gate electrode 150, the thin film transistor 301 can be operated without problems because the source connection part 130a can be conductorized by dopant doping.

FIG. 6C is a cross-sectional view of a thin film transistor 302 according to another embodiment of the present disclosure.

Referring to FIG. 6C, one end of the hydrogen control layer 142 located at the side of the source connection part 130a can be disposed within an area overlapping the gate electrode 150. When one end of the hydrogen control layer 142 located at the side of the source connection part 130a is within an area of the gate electrode 150, which is inside from one end of the gate electrode 150, if a distance between one end of the hydrogen control layer 142 and one end of the gate electrode 150 is 0.2 μm or less in a plan view, the thin film transistor 301 can operate without problem.

In the structure, when the distance between one end of the hydrogen control layer 142 and one end of the gate electrode 150 is 0.2 μm or less in a plan view, a length of the offset portion formed at the side of the source connection part 130a in the channel part 130n is not large, so the length of the effective channel part CN1 does not significantly decrease.

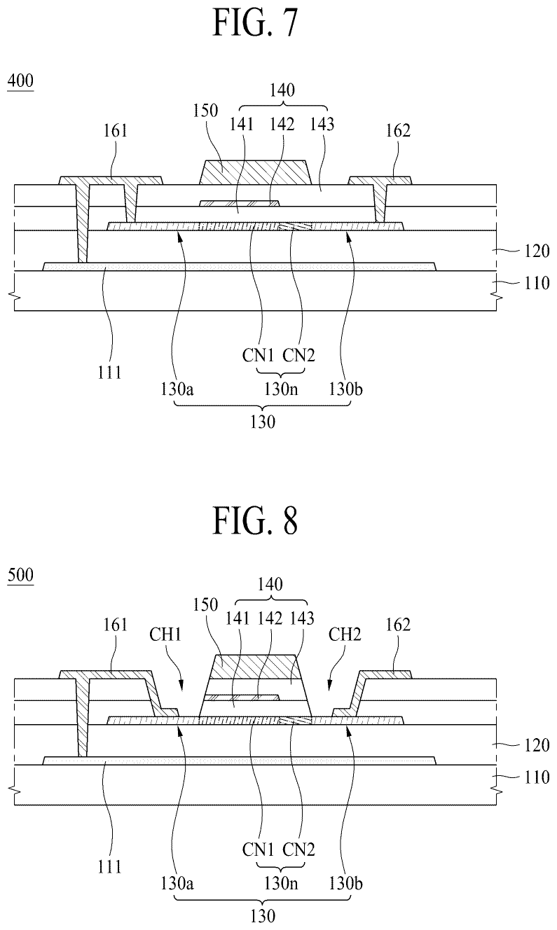

FIG. 7 is a cross-sectional view of a thin film transistor 400 according to another embodiment of the present disclosure.

Referring to FIG. 7, the source electrode 161 and the drain electrode 162 can be disposed on the gate insulating film 140. According to one embodiment of the present disclosure, the source electrode 161 and the drain electrode 162 can be disposed on the same layer as the gate electrode 150.

When the source electrode 161 and the drain electrode 162 are disposed on the gate insulating film 140, the source electrode 161 and the drain electrode 162 can be made of the same material as the gate electrode 150. The source electrode 161 and the drain electrode 162 can be formed together with the gate electrode 150 by the same process as the gate electrode 150 formation process.

FIG. 8 is a cross-sectional view of a thin film transistor 500 according to another embodiment of the present disclosure.

Referring to FIG. 8, contact holes CH1, CH2 can be formed in the gate insulating film 140. In detail, the source electrode 161 can contact the active layer 130 through the first contact hole CH1, and the drain electrode 162 can contact the active layer 130 through the second contact hole CH2.

Additionally, the region of the gate insulating film 140 that overlaps the gate electrode 150 can be patterned into the same shape as the gate electrode 150.

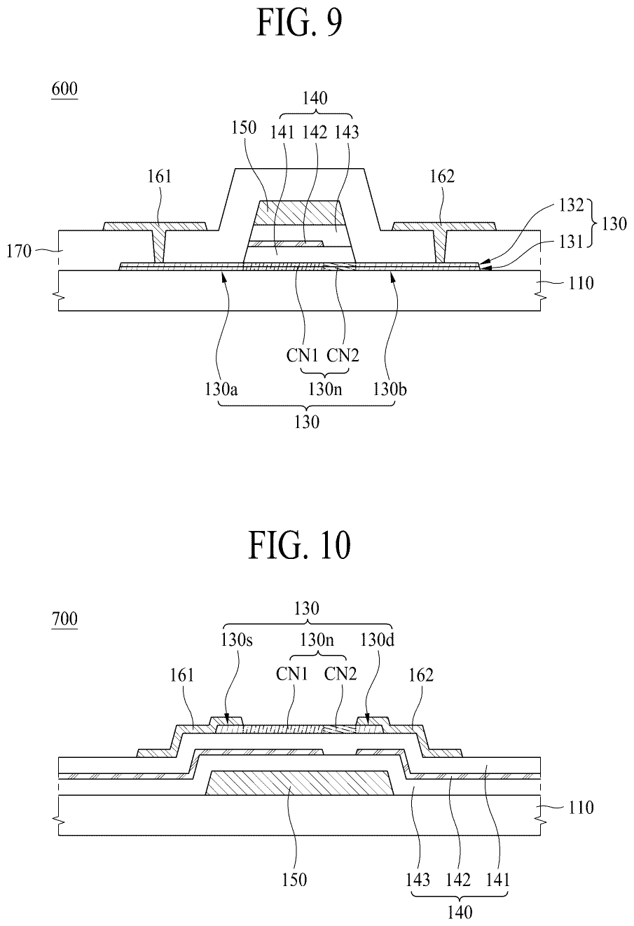

FIG. 9 is a cross-sectional view of a thin film transistor 600 according to another embodiment of the present disclosure. According to another embodiment of the present disclosure, the active layer 130 can have a multilayer structure.

Referring to FIG. 9, the active layer 130 can include a first oxide semiconductor layer 131 and a second oxide semiconductor layer 132 on the first oxide semiconductor layer 131.

The first oxide semiconductor layer 131 can serve as a support layer supporting the second oxide semiconductor layer 132. The second oxide semiconductor layer 132 can serve as a main channel layer.

The first oxide semiconductor layer 131 serving as a support layer can have excellent film stability and mechanical stability. The first oxide semiconductor layer 131 can include, for example, at least one of an IGO (InGaO) based, IGZO (InGaZnO) based, IGZTO (InGaZnSnO) based, GZTO (GaZnSnO) based, GZO (GaZnO) based, and GO (GaO) based oxide semiconductor material. However, one embodiment of the present disclosure is not limited thereto, and the first oxide semiconductor layer 131 can be made of other oxide semiconductor materials known in the art.

The second oxide semiconductor layer 132 can include at least one of oxide semiconductor materials, such as IZO (InZnO) based, FIZO (FeInZnO) based, TO (SnO) based, IGO (InGaO) based, ITO (InSnO) based, IGZO (InGaZnO) based, IGZTO (InGaZnSnO) based, GZTO (GaZnSnO) based, ITZO (InSnZnO) based, and IO (InO) based, for example. However, one embodiment of the present disclosure is not limited thereto, and the second oxide semiconductor layer 132 can be formed by other oxide semiconductor materials known in the art.

With respect to the structure of the active layer 130, another embodiment of the present disclosure is not limited to the structure of FIG. 9. The active layer 130 included in the thin film transistors 200, 300, 301, 302, 400, 500 of FIGS. 5, 6A, 6B, 6C, 7, and 8 can also have a multilayer structure. For example, the active layer 130 included in the thin film transistors 200, 300, 301, 302, 400, 500 of FIGS. 5, 6A, 6B, 6C, 7, and 8 can include a first oxide semiconductor layer 131 and a second oxide semiconductor layer 132 on the first oxide semiconductor layer 131.

FIG. 10 is a cross-sectional view of a thin film transistor 700 according to another embodiment of the present disclosure.

Referring to FIG. 10, a thin film transistor 700 according to another embodiment of the present disclosure includes a gate electrode 150 on a substrate 110, a gate insulating film 140 on the gate electrode 150, and an active layer 130 on the gate insulating film 140. In addition, the thin film transistor 700 according to another embodiment of the present disclosure can include a source electrode 161 and a drain electrode 162 disposed on the gate insulating film 140. The source electrode 161 and the drain electrode 162 are spaced apart from each other and each contacts the active layer 130.

The gate insulating film 140 includes an insulating layer 141, a hydrogen control layer 142, and a hydrogen supply layer 143. According to another embodiment of the present disclosure, in the gate insulating film 140, the hydrogen control layer 142 can be disposed between the insulating layer 141 and the hydrogen supply layer 143.

Referring to the laminated structure of the gate insulating film 140, a hydrogen supply layer 143 can be disposed on the gate electrode 150, a hydrogen control layer 142 can be disposed on the hydrogen supply layer 143, and an insulating layer 141 can be disposed on the hydrogen control layer 142.

The hydrogen control layer 142 can cover a part of the active layer 130. In a region where the gate electrode 150 and the active layer 130 overlap in a plan view, a part of the active layer 130 overlaps with the hydrogen control layer 142, and another part of the active layer 130 does not overlap with the hydrogen control layer 142.

According to another embodiment of the present disclosure, the active layer 130 includes a source contact part 130s contacting the source electrode 161, a drain contact part 130d contacting the drain electrode 162, and a channel part 130n between the source contact part 130s and the drain contact part 130d.

In addition, the active layer 130 included in the thin film transistor 700 of FIG. 10 can also have a multilayer structure. For example, the active layer 130 included in the thin film transistor 700 of FIG. 10 can include a first oxide semiconductor layer and a second oxide semiconductor layer on the first oxide semiconductor layer.

In the channel part 130n, a portion of the channel part 130n located at the side of the source contact part 130s, which is an effective channel part CN1, overlaps with the hydrogen control layer 142, and a portion of the channel part 130n located at the side of the drain contact part 130d, which is an offset portion CN2, does not overlap with the hydrogen control layer 142.

In a part of the active layer 130 that does not overlap with the source electrode 161 and the drain electrode 162, which is the channel part 130n, a portion disposed at the side of the drain electrode 162, which is the offset portion CN2, does not overlap with the hydrogen control layer 142.

The channel part 130n can include an effective channel part CN1 that overlaps with the hydrogen control layer 142 and an offset portion CN2 that does not overlap with the hydrogen control layer 142.

According to one embodiment of the present disclosure, hydrogen in the hydrogen supply layer 143 can diffuse through a portion where the hydrogen control layer 142 is not disposed and move to the offset portion CN2 of the active layer 130. As a result, free electrons are formed in the offset portion CN2, so that the offset portion CN2 can have a high carrier concentration. Therefore, according to one embodiment of the present disclosure, the offset portion CN2 can have a higher carrier concentration than the effective channel part CN1.

As illustrated in FIG. 10, a thin film transistor in which the gate electrode 150 is positioned below the active layer 130 is a thin film transistor having a bottom gate structure. On the other hand, as illustrated in FIGS. 2, 5, 6A, 6B, 6C, 7, 8, and 9, a thin film transistor in which the gate electrode 150 is disposed above the active layer 130 is called a thin film transistor having a top gate structure.

According to embodiments of the present disclosure, by disposing a hydrogen control layer 142 on a gate insulating film 140, damage to the active layer 130 and the channel part 130n can be prevented or reduced. As a result, a thin film transistor 100, 200, 300, 301. 302, 400, 500, 600, 700 according to an embodiment of the present disclosure can have excellent driving stability.

Another embodiment of the present disclosure provides a display apparatus including the thin film transistor 100, 200, 300, 301, 302, 400, 500, 600, 700 described above.

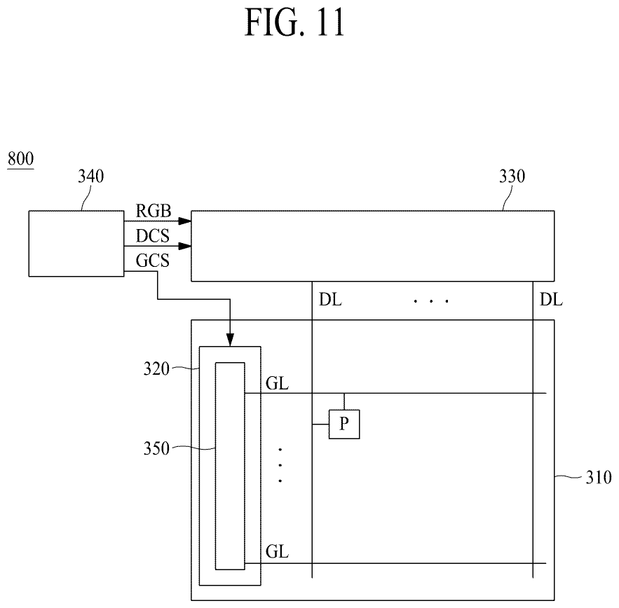

FIG. 11 is a schematic diagram of a display apparatus 800 according to one or more embodiments of the present disclosure.

Referring to FIG. 11, the display apparatus 800 according to the embodiments of the present disclosure includes a display panel 310, a gate driver 320, a data driver 330, and a control unit 340.

The gate lines GL and data lines DL are disposed on the display panel 310, and pixels P are disposed in the intersection area of the gate lines GL and data lines DL. An image is displayed by driving the pixels P.

The control unit 340 controls the gate driver 320 and the data driver 330.

The control unit 340 outputs a gate control signal GCS for controlling the gate driver 320 and a data control signal DCS for controlling the data driver 330 using a signal supplied from an external system. In addition, the control unit 340 samples input image data input from an external system, rearranges it, and supplies rearranged digital image data RGB to the data driver 330.

The gate control signal GCS includes a gate start pulse GSP, a gate shift clock GSC, a gate output enable signal GOE, a start signal Vst, and a gate clock GCLK. In addition, the gate control signal GCS can include control signals for controlling the shift register 350.

The data control signals DCS include source start pulse SSP, source shift clock signal SSC, source output enable signal SOE, and polarity control signal POL.

The data driver 330 supplies data voltage to the data lines DL of the display panel 310. In detail, the data driver 330 converts image data RGB input from the control unit 340 into analog data voltage and supplies the data voltage to the data lines DL.

The gate driver 320 can include a shift register 350.

The shift register 350 sequentially supplies gate pulses to the gate lines GL for one frame using a start signal and a gate clock transmitted from the control unit 340. Here, one frame refers to a period during which one image is output through the display panel 310. The gate pulse has a turn-on voltage capable of turning on a switching element (thin film transistor) disposed in a pixel P.

In addition, the shift register 350 supplies a gate off signal capable of turning off the switching element to the gate line GL during the remaining period during which the gate pulse is not supplied during one frame. Hereinafter, the gate pulse and the gate off signal are collectively referred to as a scan signal (SS or Scan).

According to one embodiment of the present disclosure, the gate driver 320 can be mounted on the substrate 110. In this way, a structure in which the gate driver 320 is directly mounted on the substrate 110 is called a Gate In Panel (GIP) structure. The gate driver 320 can include at least one of the thin film transistors 100, 200, 300, 301, 302, 400, 500, 600, 700 described above.

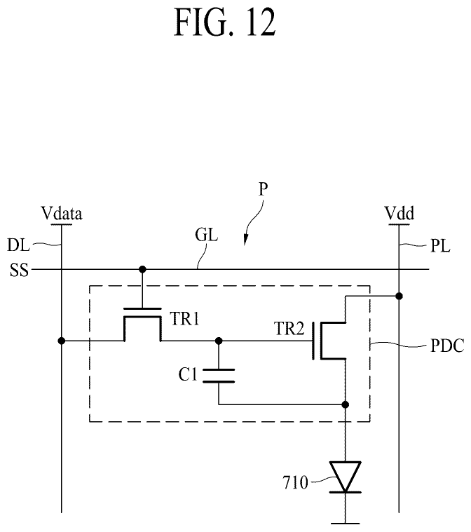

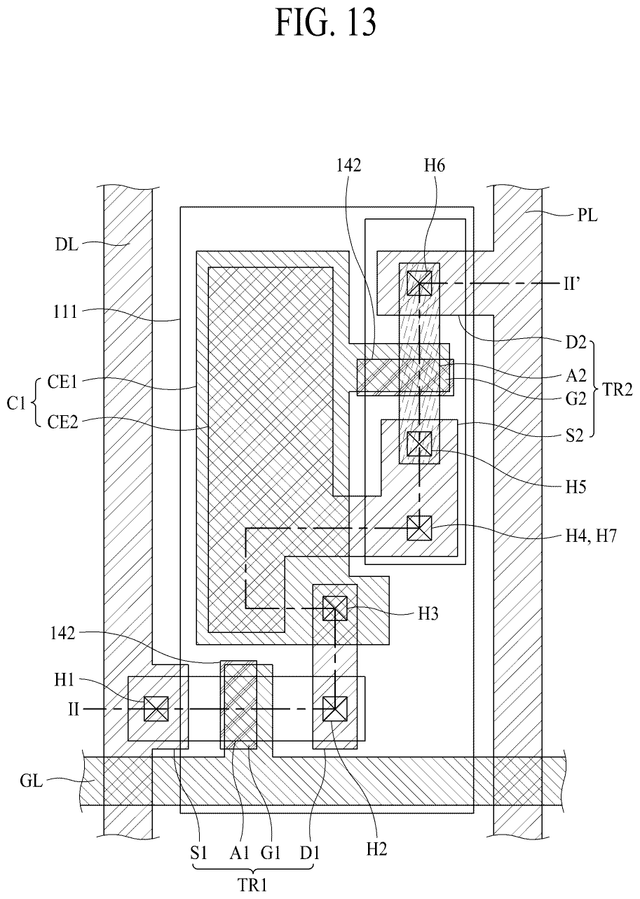

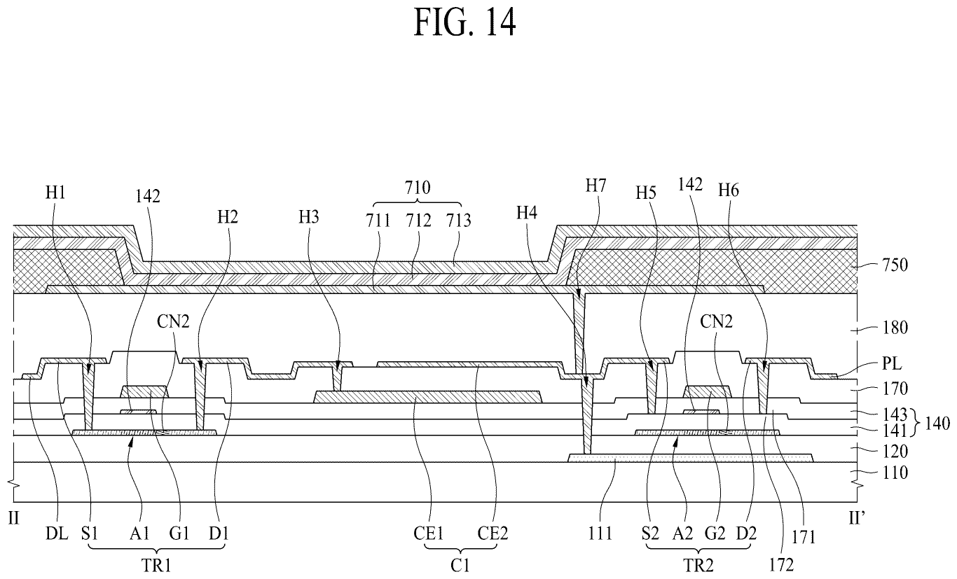

FIG. 12 is a circuit diagram for one pixel P of FIG. 11, FIG. 13 is a plan view for the pixel P of FIG. 12, and FIG. 14 is a cross-sectional view taken along line II-II′ of FIG. 13. Each of the pixels P in the display apparatus 800 or any other display apparatus discussed herein can have the configuration of the pixel P of FIGS. 12-14.

The circuit diagram of FIG. 12 is an equivalent circuit diagram for a pixel P of a display apparatus 800 including an organic light emitting diode OLED as a display element 710.

The pixel P includes a display element 710 and a pixel driver PDC that drives the display element 710.

The pixel driver PDC of FIG. 12 includes a first thin film transistor TR1 which is a switching transistor and a second thin film transistor TR2 which is a driving transistor.

A display apparatus 800 according to another embodiment of the present disclosure can include at least one of the thin film transistors 100, 200, 300, 301, 302, 400, 500, 600, 700 described above. As the first thin film transistor TR1 or the second thin film transistor TR2 of FIG. 12, any one of the thin film transistors 100, 200, 300, 301, 302, 400, 500, 600, 700 described above can be used.

The first thin film transistor TR1 is connected to the gate line GL and the data line DL, and is turned on or off by the scan signal SS supplied through the gate line GL.

The data line DL provides a data voltage Vdata to the pixel driver PDC, and the first thin film transistor TR1 controls the application of the data voltage Vdata.

The driving power line PL provides a driving voltage Vdd to the display element 710, and the second thin film transistor TR2 controls the driving voltage Vdd. The driving voltage Vdd is a pixel driving voltage for driving the organic light emitting diode OLED, which is the display element 710.

When the first thin film transistor TR1 is turned on by a scan signal SS applied through the gate line GL from the gate driver 320, the data voltage Vdata supplied through the data line DL is supplied to the gate electrode G2 of the second thin film transistor TR2 connected to the display element 710. The data voltage Vdata is charged in the first capacitor C1 formed between the gate electrode G2 and the source electrode S2 of the second thin film transistor TR2. The first capacitor C1 is a storage capacitor Cst.

The amount of current supplied to the organic light emitting diode OLED, which is a display element 710, through the second thin film transistor TR2 is controlled according to the data voltage Vdata, and accordingly, the gradation of light output from the display element 710 can be controlled.

Referring to FIG. 13 and FIG. 14, a first thin film transistor TR1 and a second thin film transistor TR2 are disposed on a substrate 110.

The substrate 110 can be made of glass or plastic. As the substrate 110, a plastic having flexible property, for example, polyimide PI, can be used.

A light shielding layer 111 can be disposed on the substrate 110. The light shielding layer 111 can block light incident from the outside to protect the active layer A2. The light shielding layer 111 can be omitted.

Although a configuration in which a light shielding layer 111 is disposed under the active layer A2 of the second thin film transistor TR2 is illustrated in FIG. 13 and FIG. 14, another embodiment of the present disclosure is not limited thereto. A light shielding layer 111 can also be arranged under the active layer A1 of the first thin film transistor TR1.

A buffer layer 120 is disposed on the light shielding layer 111. The buffer layer 120 is made of an insulating material and protects the active layers A1, A2 from moisture or oxygen flowing in from the outside.

An active layer A1 of a first thin film transistor TR1 and an active layer A2 of a second thin film transistor TR2 are disposed on a buffer layer 120.

The active layers A1, A2 include an oxide semiconductor material. According to another embodiment of the present disclosure, the active layers A1, A2 are oxide semiconductor layers made of an oxide semiconductor material.

The gate insulating film 140 is disposed on the active layers A1, A2. The gate insulating film 140 has insulating property and separates the active layers A1, A2 from the gate electrodes G1, G2. As illustrated in FIG. 14, the gate insulating film 140 may not be patterned. However, another embodiment of the present disclosure is not limited thereto, and the gate insulating film 140 can be patterned.

The gate insulating film 140 includes an insulating layer 141, a hydrogen control layer 142, and a hydrogen supply layer 143. According to one embodiment of the present disclosure, in the gate insulating film 140, the hydrogen control layer 142 can be disposed between the insulating layer 141 and the hydrogen supply layer 143.

The hydrogen control layer 142 can cover a part of the active layer A1, A2.

A gate electrode G1 of a first thin film transistor TR1 and a gate electrode G2 of a second thin film transistor TR2 are disposed on a gate insulating film 140.

The gate electrode G1 of the first thin film transistor TR1 overlaps with the active layer A1 of the first thin film transistor TR1. The gate electrode G2 of the second thin film transistor TR2 overlaps with the active layer A2 of the second thin film transistor TR2.

Referring to FIG. 13 and FIG. 14, the first capacitor electrode CE1 of the first capacitor C1 is disposed on the same layer as the gate electrodes G1, G2. The gate electrodes G1, G2 and the first capacitor electrode CE1 can be manufactured together by the same process using the same material.

An interlayer insulating layer 170 is disposed on the gate electrodes G1, G2 and the first capacitor electrode CE1.

A source electrode S1, S2 and a drain electrode D1, D2 are disposed on an interlayer insulating layer 170. According to one embodiment of the present disclosure, the source electrode S1, S2 and the drain electrode D1, D2 are distinguished only for convenience of explanation, and the source electrode S1, S2 and the drain electrode D1, D2 can be interchanged with each other. Accordingly, the source electrode S1, S2 can become the drain electrode D1, D2, and the drain electrode D1, D2 can become the source electrode S1, S2.

In addition, a data line DL and a driving power line PL are disposed on the interlayer insulating layer 170. The source electrode S1 of the first thin film transistor TR1 can be formed integrally with the data line DL. The drain electrode D2 of the second thin film transistor TR2 can be formed integrally with the driving power line PL.

According to one embodiment of the present disclosure, the source electrode S1 and the drain electrode D1 of the first thin film transistor TR1 are spaced apart from each other and are respectively connected to the active layer A1 of the first thin film transistor TR1. The source electrode S2 and the drain electrode D2 of the second thin film transistor TR2 are spaced apart from each other and are respectively connected to the active layer A2 of the second thin film transistor TR2.

In detail, the source electrode S1 of the first thin film transistor TR1 contacts the source connection of the active layer A1 through the first contact hole H1.

The drain electrode D1 of the first thin film transistor TR1 contacts the drain connection part of the active layer A1 through the second contact hole H2 and is connected to the first capacitor electrode CE1 through the third contact hole H3.

The source electrode S2 of the second thin film transistor TR2 extends over the interlayer insulating layer 170, and a portion of it functions as a second capacitor electrode CE2. The first capacitor electrode CE1 and the second capacitor electrode CE2 overlap to form a first capacitor C1.

The source electrode S2 of the second thin film transistor TR2 contacts the light shielding layer 111 through the fourth contact hole H4 and contacts the source connection of the active layer A2 through the fifth contact hole H5.

The drain electrode D2 of the second thin film transistor TR2 contacts the drain connection of the active layer A2 through the sixth contact hole H6.

The first thin film transistor TR1 includes an active layer A1, a gate electrode G1, a source electrode S1, and a drain electrode D1, and acts as a switching transistor that controls the data voltage Vdata applied to the pixel driver PDC.

The second thin film transistor TR2 includes an active layer A2, a gate electrode G2, a source electrode S2, and a drain electrode D2, and acts as a driving transistor that controls the driving voltage Vdd applied to the display element 710.

A planarization layer 180 is disposed on the source electrodes S1, S2, the drain electrodes D1, D2, the data line DL, and the driving power line PL. The planarization layer 180 planarizes the upper portions of the first thin film transistor TR1 and the second thin film transistor TR2, and protects the first thin film transistor TR1 and the second thin film transistor TR2.

The first electrode 711 of a display element 710 is disposed on a planarization layer 180. The first electrode 711 of the display element 710 is connected to a source electrode S2 of a second thin film transistor TR2 through a seventh contact hole H7 formed in the planarization layer 180.

A bank layer 750 is disposed at the edge of the first electrode 711. The bank layer 750 defines a light emitting area of the display element 710.

An organic light emitting layer 712 is disposed on a first electrode 711, and a second electrode 713 is disposed on the organic light emitting layer 712. Accordingly, a display element 710 is completed. The display element 710 illustrated in FIG. 14 is an organic light emitting diode OLED. Therefore, a display apparatus 100 according to an embodiment of the present disclosure is an organic light emitting display apparatus.

The pixel driver PDC according to another embodiment of the present disclosure can be formed in various structures other than the structures described above. The pixel driver PDC can include, for example, three or more thin film transistors and two or more capacitors.

The present disclosure described above is not limited to the above-described embodiments and the attached drawings, and it will be apparent to a person skilled in the art to which the present disclosure pertains that various substitutions, modifications, and changes are possible within a scope that does not depart from the technical details of the present disclosure.

According to one or more embodiments of the present disclosure, by selectively supplying hydrogen to the active layer using a hydrogen control layer, damage to the active layer can be prevented, and the stability and reliability of the thin film transistor can be improved.

According to one or more embodiments of the present disclosure, the gate insulating film of the thin film transistor includes a hydrogen supply layer and a hydrogen control layer. Through the hydrogen supply layer and hydrogen control layer disposed in the gate insulating film, hydrogen can be supplied to the drain connection side of the channel part. As a result, according to one or more embodiments of the present disclosure, the carrier concentration in the side of the drain connection part of the channel part is increased, thereby preventing or alleviating electric field concentration at the side of the drain connection part.

According to one or more embodiments of the present disclosure, as electric field concentration at the side of the drain connection part in the channel part is alleviated, damage to the active layer can be prevented, and thus damage to the thin film transistor can be prevented or suppressed. According to one or more embodiments of the present disclosure, as damage to the active layer is prevented, the thin film transistor can have excellent stability.

According to one or more embodiments of the present disclosure, the electric field applied to the drain region is mitigated, thereby preventing damage to the active layer and preventing defects or damage in the oxide semiconductor thin film transistor.

The display apparatus according to one or more embodiments of the present disclosure includes a thin film transistor having the excellent stability. As a result, the display apparatus according to one or more embodiments of the present disclosure can exhibit stable display performance.

1. A thin film transistor comprising:
an active layer;
a gate electrode spaced apart from the active layer; and
a gate insulating film between the active layer and the gate electrode,
wherein the gate insulating film comprises:
an insulating layer;
a hydrogen control layer on the insulating layer; and
a hydrogen supply layer on the hydrogen control layer,
wherein the hydrogen supply layer has a higher hydrogen concentration than the insulating layer, and
wherein in a region where the gate electrode and the active layer overlap in a plan view, a portion of the active layer overlaps the hydrogen control layer and another portion of the active layer does not overlap the hydrogen control layer.

2. The thin film transistor of claim 1,
wherein the active layer comprises:
a channel part overlapping the gate electrode;
a source connection part connected to one side of the channel part; and
a drain connection part connected to another side of the channel part,
wherein a portion of the channel part adjacent to the source connection part overlaps the hydrogen control layer, and
wherein a portion of the channel part adjacent to the drain connection part does not overlap the hydrogen control layer.

3. The thin film transistor of claim 2,
wherein the hydrogen control layer does not overlap a boundary between the channel part and the drain connection part in a plan view.

4. The thin film transistor of claim 2,
wherein the channel part comprises:
an effective channel part overlapping the hydrogen control layer; and
an offset portion not overlapping the hydrogen control layer.

5. The thin film transistor of claim 4,
wherein the offset portion has a higher carrier concentration than the effective channel part.

6. The thin film transistor of claim 4,
wherein a carrier concentration in the offset portion increases in a direction from the effective channel part toward the drain connection part.

7. The thin film transistor of claim 1,
wherein the hydrogen control layer includes metal oxide, and
wherein the metal oxide includes at least one of aluminum (Al), tungsten (W), titanium (Ti), chromium (Cr), vanadium (V), manganese (Mn), tantalum (Ta), hafnium (Hf), zirconium (Zr), nickel (Ni), molybdenum (Mo), and beryllium (Be).

8. The thin film transistor of claim 1,
wherein the insulating layer includes at least one of silicon oxide (SiOx), aluminum oxide (AlOx), tantalum oxide (TaOx), hafnium oxide (HfOx), and zirconium oxide (ZrOx), and
wherein the hydrogen supply layer includes silicon nitride (SiNx).

9. The thin film transistor of claim 1, wherein a thickness of the hydrogen control layer is 5 nm to 10 nm.

10. The thin film transistor of claim 2,
wherein a gradient of a carrier concentration variation at a boundary between the channel part and the drain connection part is smaller than a gradient of a carrier concentration variation at a boundary between the channel part and the source connection part.

11. The thin film transistor of claim 1 further comprising:
a source electrode and a drain electrode spaced apart from each other and contacting the active layer respectively,
wherein the active layer comprises:
a source contact part contacting the source electrode;
a drain contact part contacting the drain electrode; and
a channel part between the source contact part and the drain contact part,
wherein a portion of the channel part adjacent to the source contact part overlaps the hydrogen control layer, and
wherein a portion of the channel part adjacent to the drain contact part does not overlap the hydrogen control layer.

12. The thin film transistor of claim 11, wherein the channel part comprises:
an effective channel part overlapping the hydrogen control layer; and
an offset portion not overlapping the hydrogen control layer.

13. The thin film transistor of claim 12,
wherein the offset portion has a higher carrier concentration than the effective channel part.

14. A display apparatus comprising:
the thin film transistor of claim 1.

15. The display apparatus of claim 14, further comprising:
a plurality of pixels disposed on a substrate and configured to display images; and
a gate driver disposed on the substrate and configured to supply gate signals to the plurality of pixels,
wherein the gate driver includes a plurality of thin film transistors, at least one of the plurality of thin film transistors being the thin film transistor comprising the active layer, the gate electrode and the gate insulating film.

16. The display apparatus of claim 15, wherein the gate driver is directly mounted on the substrate and has a gate in panel (GIP) structure.

17. The display apparatus of claim 15, wherein each of the plurality of pixels includes a display element and a pixel driver configured to drive the display element,
wherein the pixel driver includes a switching transistor and a driving transistor, and
wherein at least one of the switching transistor and the driving transistor is the thin film transistor comprising the active layer, the gate electrode and the gate insulating filmof claim 1.

18. The display apparatus of claim 14, further comprising:
a plurality of pixels disposed on a substrate and configured to display images,
wherein each of the plurality of pixels includes a display element and a pixel driver configured to drive the display element,
wherein the pixel driver includes a switching transistor and a driving transistor, and
wherein at least one of the switching transistor and the driving transistor is the thin film transistor comprising the active layer, the gate electrode and the gate insulating filmof
